(19) United States
(12) Patent Application Publication
(10) Pub. No.: US 2025/0048913 A1
(43) Pub. Date: Feb. 6, 2025

(54) DISPLAY DEVICE AND METHOD OF MANUFACTURING THE SAME

(71) Applicant: Samsung Display Co., LTD., Yongin-si (KR)

(72) Inventors: OHJUNE KWON, Yongin-si (KR); SOYOUNG LEE, Yongin-si (KR)

(21) Appl. No.: 18/647,274

(22) Filed: Apr. 26, 2024

(30) Foreign Application Priority Data
Aug. 3, 2023 (KR) 10-2023-0101735

(51) Int. Cl. H10K 77/10; H10K 59/12; H10K 59/131

(52) U.S. Cl. CPC H10K 77/10; H10K 59/1201; H10K 59/131

(57) ABSTRACT

A display device includes a base substrate divided into a display area and at least one edge area adjacent to the display area. The base substrate includes an upper surface, a rear surface facing the upper surface, a first inclined surface forming a first inclined angle with the upper surface, and a second inclined surface forming a second inclined angle with the rear surface. The display device includes a display panel disposed on the upper surface of the base substrate, wherein the first inclined surface and the second inclined surface are defined in the at least one edge area.

This application claims priority to Korean Patent Application No. 10-2023-0101735, filed on Aug. 3, 2023, and all the benefits accruing therefrom under 35 U.S.C. § 119, the content of which in its entirety is herein incorporated by reference.

### BACKGROUND

### 1. Field

Embodiments relate to a display device and a method of manufacturing the same.

More particularly, the embodiments relate to a display device including a substrate including an inclined surface and a method of manufacturing the same.

### 2. Description of the Related Art

A display device is a device that may display an image for providing visual information to a user. Among display devices, an organic light emitting diode display has recently attracted attention.

A display device may include a substrate including a glass. The substrate may be formed through an etching process. Recently, etching processes using a laser to etch the substrate have been widely used.

### SUMMARY

Embodiments provide a display device with improved impact resistance.

Embodiments provide a method of manufacturing the display device.

A display device according to an embodiment may include a base substrate divided into a display area and at least one edge area adjacent to the display area, the base substrate including an upper surface, a rear surface facing the upper surface, a first inclined surface forming a first inclined angle with the upper surface, and a second inclined surface forming a second inclined angle with the rear surface and a display panel disposed on the upper surface of the base substrate. The first inclined surface and the second inclined surface are defined in the at least one edge area.

In an embodiment, an intersection point, where the first inclined surface and the second inclined surface intersect, may be defined on the base substrate.

In an embodiment, the intersection point may be located between a first plane extending in a direction parallel to the upper surface and a second plane extending in a direction parallel to the rear surface.

In an embodiment, the intersection point may be located on a virtual horizontal line that bisects a thickness of the base substrate.

In an embodiment, a shortest distance from the first plane to the intersection point may be substantially equal to a shortest distance from the second plane to the intersection point.

In an embodiment, the first inclined angle may be substantially equal to the second inclined angle.

In an embodiment, the at least one edge area may be adjacent to an outside of the display area.

In an embodiment, the upper surface may include: four sides that overlap the outside of the display area; and at least one corner area formed by two adjacent sides included among the four sides and intersecting with each other, and the first inclined surface may extend from at least one of the four sides

In an embodiment, the base substrate may further include a pad area configured to transmit electrical signals to the display area, and the first inclined surface may extend from a side included among the four sides and located adjacent to the pad area.

In an embodiment, the at least one edge area may overlap the at least one corner area.

A method of manufacturing a display device according to an embodiment includes forming at least one first hole in a first irradiation direction on a rear surface of a substrate, the substrate including an upper surface and the rear surface facing the upper surface, forming at least one second hole in a second irradiation direction different from the first irradiation direction on the rear surface, filling the at least one first hole and the at least one second hole with an etchant, forming a first inclined surface along the at least one first hole, forming a second inclined surface along the at least one second hole, and forming a base substrate including the first inclined surface and the second inclined surface.

In an embodiment, the at least one first hole and the at least one second hole may be spaced apart from each other.

In an embodiment, a length of the at least one first hole in the first irradiation direction may be longer than a length of the at least one second hole in the second irradiation direction.

In an embodiment, forming the at least one first hole may include forming a plurality of first holes along a first direction parallel to the rear surface, and at least one forming the second hole may include forming a plurality of second holes along the first direction.

In an embodiment, the at least one first hole and the at least one second hole may be arranged side by side in a second direction perpendicular to the first direction.

In an embodiment, the at least one first hole and the at least one second hole may be arranged obliquely to the first direction and a second direction perpendicular to the first direction.

In an embodiment, forming the first inclined surface may include forming a dummy substrate including a third inclined surface by extending the at least one first hole to the upper surface through the etchant and forming of the base substrate may include separating the base substrate from the dummy substrate.

In an embodiment, forming the dummy substrate may include removing a portion of the substrate using the etchant, and the portion is formed at an intersection of the second inclined surface, the third inclined surface, and the rear surface using the etchant.

In an embodiment, filling the etchant may include applying the etchant on the rear surface of the substrate.

In an embodiment, an intersection point, where the first inclined surface and the second inclined surface intersect, may be located between a first plane extending in a direction parallel to the upper surface and a second plane extending in a direction parallel to the rear surface.

A display device according to embodiments of the present disclosure may include a base substrate including a first inclined surface, a second inclined surface, and an intersection formed by meeting the first inclined surface and the second inclined surface. As the first inclined surface has a first inclined angle with the upper surface, and the second inclined surface has a second inclined angle with the rear surface, the impact resistance of the display device may be improved.

A method of manufacturing the display device according to embodiments of the present disclosure may include forming a first hole and a second hole, forming the first inclined surface and the second inclined surface using an etchant, and forming the base substrate from a substrate. Accordingly, the process time and cost of the display device manufacturing process may be reduced by simultaneously performing the substrate separation process and an etching process. In some embodiments, a partial area of the substrate formed by the meeting of the rear surface of the substrate, the second inclined surface, and the third inclined surface of a dummy substrate is removed through the etchant, and chipping and cracking may thereby be prevented during the separation process of the base substrate.

### BRIEF DESCRIPTION OF THE DRAWINGS

Illustrative, non-limiting embodiments will be more clearly understood from the following detailed description in conjunction with the accompanying drawings.

FIG. 1 is a plan view illustrating a display device according to an embodiment.

FIG. 2 is a cross-sectional view illustrating the display device of FIG. 1 taken along the I-I′ line.

FIG. 3 is a cross-sectional view illustrating an enlarged cross-section of area A of FIG. 2.

FIG. 4 is a cross-sectional view illustrating an enlarged cross-section of area B of FIG. 2.

FIGS. 5, 6, 7, 8, and 9 are perspective views illustrating a method of manufacturing a display device according to an embodiment.

FIGS. 10 and 11 are perspective views illustrating a method of manufacturing a display device according to an embodiment.

FIG. 12 is a plan view illustrating a display device according to an embodiment.

FIG. 13 is a plan view illustrating a display device according to an embodiment.

FIG. 14 is a plan view illustrating a display device according to an embodiment.

### DETAILED DESCRIPTION

Hereinafter, display devices in accordance with embodiments will be described in more detail with reference to the accompanying drawings. The same reference numerals are used for the same components in the drawings, and redundant descriptions of the same components will be omitted.

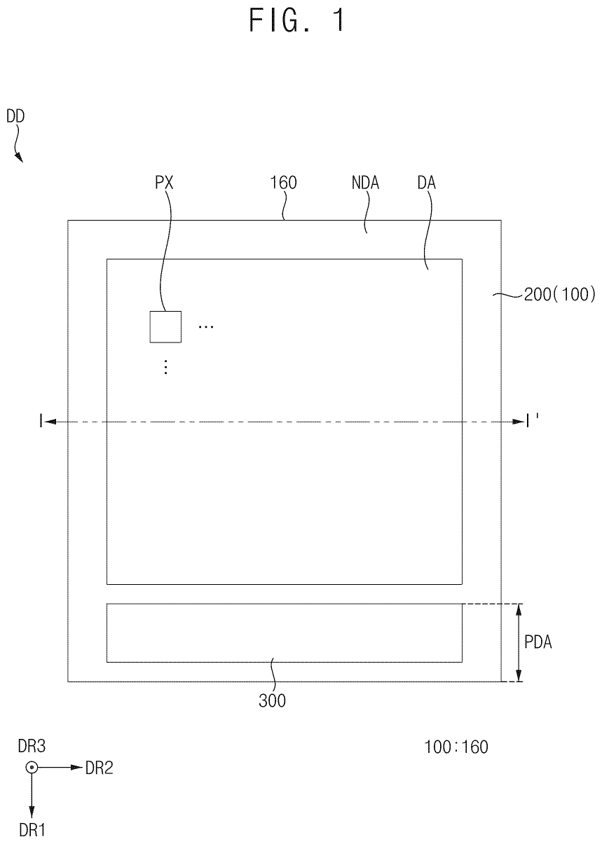

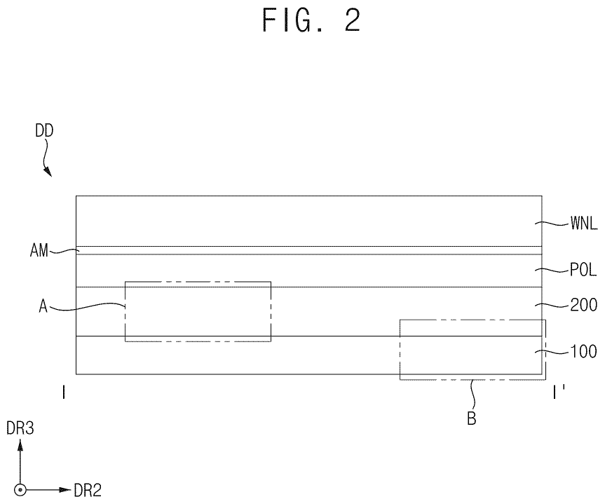

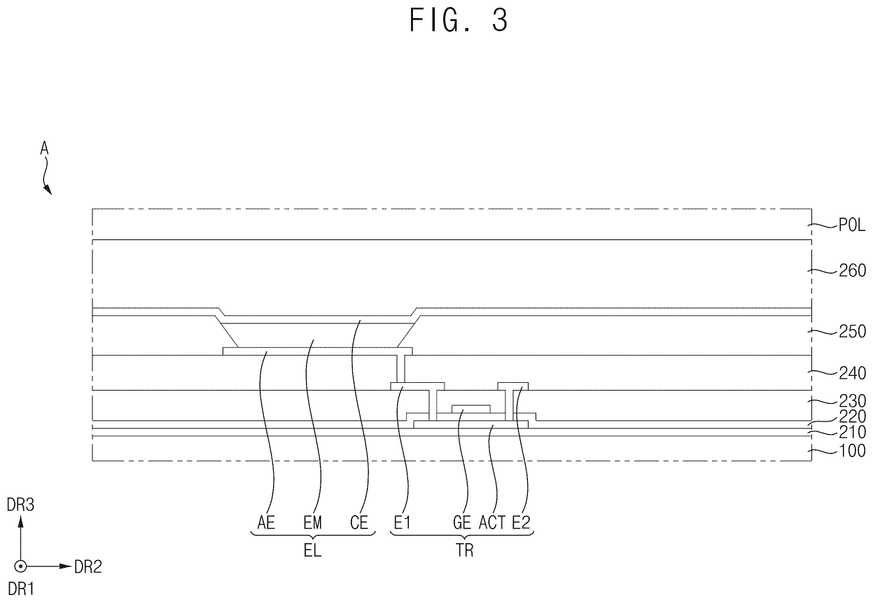

FIG. 1 is a plan view illustrating a display device according to an embodiment. FIG. 2 is a cross-sectional view illustrating the display device of FIG. 1 taken along the I-I′ line. FIG. 3 is a cross-sectional view illustrating an enlarged cross-section of area A of FIG. 2.

Referring to FIGS. 1 and 2, a display device DD according to an embodiment of the present disclosure may include a base substrate 100, a display panel 200, a driving member 300, a polarizing member POL, an adhesive member AM, and a window member WNL.

The base substrate 100 may include a display area DA, a non-display area NDA, a pad area PDA, and an edge area 160. A plurality of pixels PX may be arranged in the display area DA. Each of the plurality of pixels PX may emit light. The plurality of pixels PX may be arranged in a matrix form. For example, the plurality of pixels PX may be arranged in a first direction DR1 and may be arranged in a second direction DR2 perpendicular to the first direction DR1. Accordingly, the display area DA may display an image formed by light emitted from the pixels PX.

In this specification, a plane may be defined by the first direction DR1 and the second direction DR2. For example, the second direction DR2 may be perpendicular to the first direction DR1. In an example, a third direction DR3 may be perpendicular to the plane.

The non-display area NDA may be adjacent to the display area DA. For example, the non-display area NDA may surround the display area DA. The pad area PDA may be adjacent to the non-display area NDA. The pad area PDA may be spaced apart from one side of the display area DA in the first direction DR1.

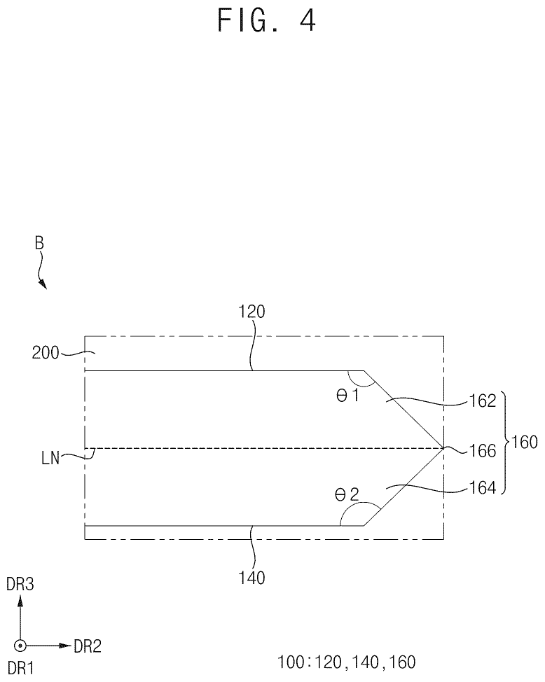

In an embodiment, the edge area 160 may be located outside the display area DA. For example, the edge area 160 may be located on the outside of an upper surface of the base substrate (e.g., an upper surface 120 of the base substrate in FIG. 4). Specifically, for example, the upper surface of the base substrate may include four sides, and the edge area 160 may be adjacent to the four sides. In FIG. 1, the upper surface of the base substrate is shown as including the four sides, but aspects of the present disclosure are not limited thereto and may include a various number of sides.

The base substrate 100 may include materials such as, for example, glass, quartz, plastic, and the like. The materials may be used alone or in combination with each other.

Referring to FIGS. 2 and 3, the display panel 200 may be disposed on the base substrate 100. The display panel 200 may include a buffer layer 210, an active pattern ACT, a first insulating layer 220, a gate electrode GE, a second insulating layer 230, a first electrode E1, a second electrode E2, a third insulating layer 240, a pixel electrode AE, a fourth insulating layer 250, a light emitting layer EM, a common electrode CE, and an encapsulation layer 260. The transistor TR may include the active pattern ACT, the gate electrode GE, the first electrode E1, and the second electrode E2. The light emitting element EL may include the pixel electrode AE, the light emitting layer EM, and the common electrode CE.

The buffer layer 210 may be disposed on the base substrate 100. The buffer layer 210 may include an inorganic insulating material. The buffer layer 210 may prevent impurities from diffusing from the base substrate 100 to the active pattern ACT.

The active pattern ACT may be disposed on the buffer layer 210. For example, the active pattern ACT may include a silicon semiconductor, an oxide semiconductor, and the like. The silicon semiconductor may include amorphous silicon, polycrystalline silicon, and the like. The active pattern ACT may include a source region, a drain region, and a channel region.

The channel region may be disposed between the source region and the drain region.

The first insulating layer 220 may be disposed on the buffer layer 210. The first insulating layer 220 may cover the active pattern ACT on the buffer layer 210. For example, the first insulating layer 220 may have a substantially uniform thickness along the profile of the active pattern ACT. In some embodiments, the first insulating layer 220 may sufficiently cover the active pattern ACT and may have a substantially flat upper surface without creating a step around the active pattern ACT.

The first insulating layer 220 may include an inorganic insulating material. The inorganic insulating material may include materials such as, for example, silicon nitride (SiNx), silicon oxide (SiOx), silicon oxynitride (SiOxNy), and the like. The materials may be used alone or in combination with each other.

The gate electrode GE may disposed on the first insulating layer 220. The gate electrode GE may overlap the channel region of the active pattern ACT. The gate electrode GE may include elements such as, for example, aluminum (Al), platinum(Pt), palladium(Pd), silver(Ag), magnesium(Mg), Nickel (Ni), neodymium (Nd), iridium (Ir), single (Cr), lithium (Li), lumped (Ca), molybdenum (Mo), titanium (Ti), tungsten (W), copper (Cu), and the like. The elements may be used alone or in combination each other.

The gate electrode GE and the first insulating layer 220 may mask the channel region of the active pattern ACT. In some embodiments, the width of the gate electrode GE and the first insulating layer 220 may be narrower than the width of the active pattern ACT. However, aspects of the present disclosure are not limited thereto.

The second insulating layer 230 may be disposed on the first insulating layer 220. The second insulating layer 230 may cover the gate electrode GE. For example, the second insulating layer 230 may have a substantially uniform thickness along the profile of the gate electrode GE. In some embodiments, the second insulating layer 230 may sufficiently cover the gate electrode GE and may have a substantially flat upper surface without creating a step around the gate electrode GE.

The second insulating layer 230 may include an inorganic insulating material. The inorganic insulating material may include elements such as, for example, silicon nitride (SiNx), silicon oxide (SiOx), silicon oxynitride (SiOxNy), and the like. The elements may be used alone or in combination with each other.

The first electrode E1 and the second electrode E2 may be disposed on the second insulating layer 230. The first electrode E1 and the second electrode E2 may contact the source region and the drain region of the active pattern ACT, respectively, through a contact hole penetrating the first insulating layer 220 and the second insulating layer 230. The first electrode E1 and the second electrode E2 may include materials such as, for example, metal, alloy, conductive metal oxide, conductive metal nitride, transparent conductive material, and the like. The materials may be used alone or in combination with each other. The active pattern ACT, gate electrode GE, first electrode E1, and second electrode E2 may form the transistor TR.

The third insulating layer 240 may be disposed on the second insulating layer 230. The third insulating layer 240 may cover the first electrode E1 and the second electrode E2. The third insulating layer 240 may include an organic insulating material.

The pixel electrode AE may be disposed on the third insulating layer 240. The pixel electrode AE may contact the first electrode E1 or the second electrode E2 through a contact hole penetrating the third insulating layer 240. Accordingly, the pixel electrode AE may be electrically connected to the transistor TR.

The fourth insulating layer 250 may be disposed on the third insulating layer 240. The fourth insulating layer 250 may partially cover the pixel electrode AE on the third insulating layer 240. The fourth insulating layer 250 may have a pixel opening that exposes at least a portion of the upper surface of the pixel electrode AE. The fourth insulating layer 250 may include an organic insulating material.

The light emitting layer EM may be disposed on the pixel electrode AE. For example, the light emitting layer EM may be disposed on the pixel electrode AE exposed from the fourth insulating layer 250. In an embodiment, the light emitting layer EM may include a multilayer structure including a hole injection layer, a hole transport layer, an organic light emitting layer, an electron transport layer, and an electron injection layer.

The common electrode CE may be disposed on the light emitting layer EM and the fourth insulating layer 250. The light emitting layer EM may emit light based on the voltage difference between the pixel electrode AE and the common electrode CE.

The encapsulation layer 260 may be disposed on the light emitting element EL. For example, the encapsulation layer 260 may be disposed on the common electrode CE. The encapsulation layer 260 may include at least one inorganic encapsulation layer and at least one organic encapsulation layer. The encapsulation layer ENL may prevent oxygen and moisture from penetrating into the light emitting element EL and/or the circuit element layer.

The polarizing member POL may be disposed on the display panel 200. The polarizing member POL may block external light incident on the display panel 200 from the outside.

The window member WNL may be disposed on the polarizing member POL. The window member WNL may have a transparent portion corresponding to the display area DA of the display device DD. In some aspects, the window member WNL may protect the display panel 200 from external shock.

The adhesive member AM may be disposed between the polarizing member POL and the window member WNL. For example, the adhesive member AM may attach the polarizing member POL and the window member WNL. The adhesive member AM may include an adhesive or resin such as, for example, an optical clear adhesive OCA, a pressure sensitive adhesive PSA, a photocurable resin, a thermosetting resin, etc. The adhesives or resins may be used alone or in combination with each other.

The driving member 300 may be disposed such that the driving member 300 overlaps the non-display area NDA and the pad area PDA. The driving member 300 may include a plurality of pad electrodes, a plurality of driving chips, a circuit board, a flexible circuit film, and the like. The plurality of pad electrodes may be electrically connected to the circuit board. Specifically, for example, the plurality of pad electrodes may be electrically connected to the circuit board through the flexible circuit film. The plurality of driving chips and the circuit board may serve to transmit external signals to the plurality of pixels PX.

In some aspects, the plurality of driving chips may be disposed on the base substrate 100. The circuit board may be spaced apart from the base substrate 100. In some embodiments, the circuit board may be placed below the base substrate 100. In this case, the flexible circuit film may have a curved shape. However, aspects of the present disclosure are not limited thereto.

FIG. 4 is a cross-sectional view illustrating an enlarged cross-section of area B of FIG. 2. For example, FIG. 4 is an enlarged cross-sectional view of at least one of the edge area 160 included in the base substrate 100 of FIG. 2.

Referring to FIG. 4, the base substrate 100 may include the upper surface 120 and a rear surface 140 facing the upper surface 120. The side of the base substrate 100 may include an edge area 160. The edge area 160 may be defined by a first inclined surface 162 and a second inclined surface 164 area. Specifically, for example, the edge area 160 may be an area surrounded by the first inclined surface 162 and the second inclined surface 164.

The first inclined surface 162 may be adjacent to the upper surface 120 of the base substrate 100. For example, the first inclined surface 162 may form a first inclined angle θ1 with the upper surface 120 of the base substrate 100. Specifically, for example, the first inclined angle θ1 may be formed at a portion where the upper surface 120 and the first inclined surface 162 meet. The first inclined angle θ1 may be an obtuse angle greater than 90° and less than 180°. In other words, for example, the first inclined surface 162 may be inclined from the upper surface 120 toward a diagonal direction between the second direction DR2 and a direction opposite to the third direction DR3. References described herein to instances in which two or more components (e.g., upper surface 120 and first inclined surface 162) “meet” may be referred to as an “intersecting” of the two or more components.

The second inclined surface 164 may be adjacent to the rear surface 140 of the base substrate 100. For example, the second inclined surface 164 may form a second inclined angle θ2 with the rear surface 140 of the base substrate 100. Specifically, for example, the second inclined angle θ2 may be formed at a portion where the rear surface 140 and the second inclined surface 164 meet. The second inclined angle θ2 may be an obtuse angle greater than 90° and less than 180°. In other words, for example, the second inclined surface 164 may be inclined from the rear surface 140 toward a diagonal direction between a direction opposite to the second direction DR2 and a direction opposite to the third direction DR3.

In an embodiment, an intersection point 166 may be defined by the intersection of the first inclined surface 162 and the second inclined surface 164. For example, the intersection point 166 may be an area including a straight line formed by meeting the first inclined surface 162 and the second inclined surface 164. Specifically, for example, the straight line may be parallel to the first direction DR1 and parallel to the upper surface 120 and the rear surface 140.

The edge area 160 surrounded by the first inclined surface 162 and the second inclined surface 164 may protrude from the center of the base substrate 100 in the second direction DR2. For example, the protruding edge area 160 may have a triangular planar shape. Specifically, for example, the planar shape may include a portion where the first inclined surface 162 and the upper surface 120 meet, a portion where the second inclined surface 164 and the rear surface 140 meet, and an intersection point 166. Additionally, for example, the planar shape may extend in the first direction DR1. Accordingly, the edge area 160 may have the three-dimensional shape of a triangular pillar parallel to the first direction DR1.

Although not shown in FIG. 4, the projection direction of the planar shape of the edge area 160 may not be limited to the second direction DR2. The protrusion direction may be any direction that may be parallel to the base substrate 100.

In an embodiment, the intersection point 166 may be located between a first plane in which the upper surface 120 extends, in the first direction DR1 and the second direction DR2, and a second plane in which the rear surface 140 extends, in the first direction DR1 and the second direction DR2. In other words, the intersection point 166 may not be located above the first plane or below the second plane.

The intersection point 166 may be spaced apart from the first plane and the second plane. In other words, for example, the intersection point 166 may not meet the first plane and the second plane. Specifically, for example, the first inclined surface 162 may not be parallel to the upper surface 120, and the first inclined surface 162 may not meet the upper surface 120 perpendicularly. That is, for example, the first inclined surface 162 may meet the upper surface 120 according to a direction that is not perpendicular to the upper surface 120. In some embodiments, the second inclined surface 164 may not be parallel to the rear surface 140, and may not meet the rear surface 140 perpendicularly. Accordingly, since friction does not occur due to the vertical plane, the impact resistance of the display device DD can be improved.

As described herein, the first inclined angle θ1 and the second inclined angle θ2 may be obtuse angles greater than 90° and less than 180°. Accordingly, the first inclined surface 162 and the second inclined surface 164 may meet each other, and the intersection point 166 may be located between (e.g., only between) the first plane and the second plane.

In an embodiment, the intersection point 166 may be located on an virtual horizontal line LN that bisects the thickness of the base substrate 100. Specifically, a planar shape consisting of the first inclined surface 162, the upper surface 120, and the virtual horizontal line LN and a planar shape consisting of the second inclined surface 164, the rear surface 140, and the virtual horizontal line LN may be symmetrical about the virtual horizontal line LN.

However, aspects of the present disclosure are not limited thereto. For example, the intersection point 166 may be located on the virtual horizontal line LN, and the planar shape consisting of the first inclined surface 162, the upper surface 120, and the virtual horizontal line LN and the planar shape consisting of the second inclined surface 164, the rear surface 140, and the virtual horizontal line LN may be asymmetric about the virtual horizontal line LN.

In an embodiment, a shortest distance from the first plane to the intersection point 166 may be substantially equal to a shortest distance from the second plane to the intersection point 166. In this case, the intersection point 166 may not be disposed between a plane that overlaps the upper surface 120 of the first plane and a plane that overlaps the rear surface 140 of the second plane.

However, aspects of the present disclosure are not limited thereto, and the shortest distance from the first plane to the intersection point 166 may not be the substantially equal to the shortest distance from the second plane to the intersection point 166. For example, the shortest distance from the first plane to the intersection point 166 may be different from (e.g., shorter than) the shortest distance from the second plane to the intersection point 166.

In an embodiment, the intersection point 166 may be spaced apart from the virtual horizontal line LN bisecting the thickness of the base substrate 100 in the third direction DR3. For example, the intersection point 166 may be located on another horizontal line obtained by moving the virtual horizontal line LN in parallel in the third direction DR3. Specifically, for example, the first inclined surface 162 and the second inclined surface 164 may be located above the virtual horizontal line LN, and the second inclined surface 164 may meet the virtual horizontal line LN.

In an embodiment, the intersection point 166 may be spaced apart from the virtual horizontal line LN bisecting the thickness of the base substrate 100 in a direction opposite to the third direction DR3. For example, the intersection point 166 may be located on another horizontal line obtained by moving the virtual horizontal line LN parallel to the third direction DR3. Specifically, for example, the first inclined surface 162 and the second inclined surface 164 may be located below the virtual horizontal line LN, and the first inclined surface 162 may meet the virtual horizontal line LN.

A size of the first inclined angle θ1 formed by the upper surface 120 and the first inclined surface 162 may be substantially equal to a size of the second inclined angle θ2 formed by the rear surface 140 and the second inclined surface 164. In some embodiments, the size of the first inclined angle θ1 and the size of the second inclined angle θ2 may be different. For example, the size of the first inclined angle θ1 may be smaller than the size of the second inclined angle θ2. Specifically, for example, the first inclined angle θ1 and the second inclined angle θ2 may have an angle between 90° and 180°, and the size of the first inclined angle θ1 may be smaller than the size of the second inclined angle θ2. That is, In an example, the first inclined angle θ1 may not be 90°, and the second inclined angle θ2 may not be 180°. Additionally, for example, the size of the first inclined angle θ1 may be larger than the size of the second inclined angle θ2.

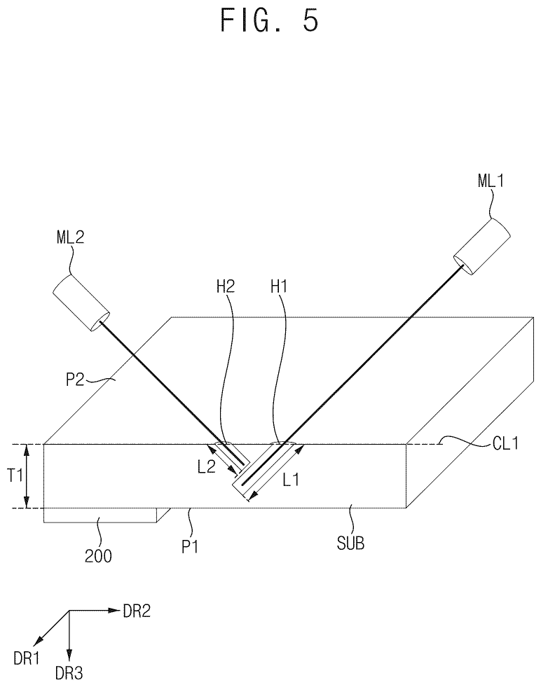

FIGS. 5, 6, 7, 8, and 9 are perspective views illustrating a method of manufacturing a display device according to an embodiment.

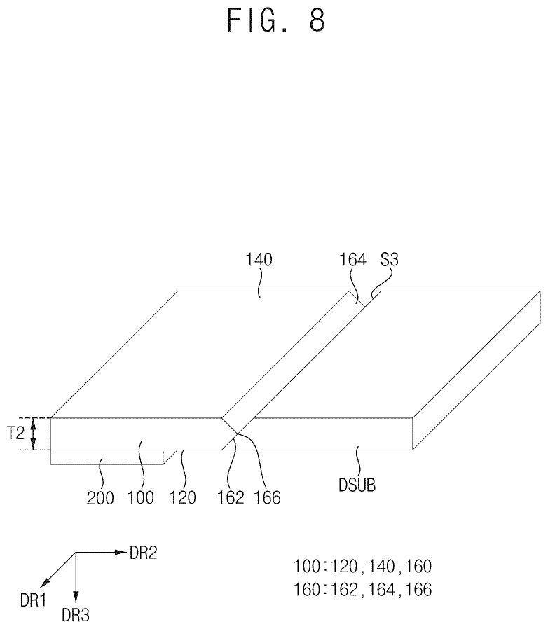

Referring to FIG. 5, the method may include forming at least one first hole H1 and at least one second hole H2 in a rear surface P2 of the substrate SUB. For example, the method may include forming the first hole H1 in a first radiation direction, and forming the second hole H2 in a second radiation direction different from the first radiation direction. Specifically, for example, the first radiation direction and the second radiation direction may meet at a virtual point within the thickness of the substrate SUB. Accordingly, the first hole H1 and the second hole H2 may meet within the thickness of the substrate SUB to form an intersection (e.g., intersection point 166 in FIG. 8). In this case, for example, the first radiation direction and the second radiation direction may not be parallel or perpendicular to each other.

In an embodiment, the method may include forming the first hole H1 and the second hole H2 on the rear surface P2 of the substrate SUB through light sources emitted from a first laser ML1 and a second laser ML2. However, the equipment for forming the first hole H1 and the second hole H2 may not be limited to a laser apparatus, and the equipment may include various cutting apparatuses (e.g., sand blaster) capable of forming holes on the rear surface of the substrate SUB.

In an embodiment, the first hole H1 formed in the first irradiation direction may be spaced apart from the second hole H2 formed in the second irradiation direction. That is, for example, the first hole H1 formed by the first laser and the second hole H2 formed by the second laser may not meet each other. However, the extension line of the first hole H1 in the first radiation direction and the extension line of the second hole H2 in the second radiation direction may meet at a location between an upper surface P1 and the rear surface P2 of the substrate SUB.

In an embodiment, a first length L1 of the first hole H1 in the first radiation direction may be longer than a second length L2 of the second hole H2 in the second radiation direction. Specifically, for example, an extension line of the second hole H2 in the second irradiation direction may meet the first hole H1 inside the substrate SUB. However, aspects of the present disclosure are not limited thereto, and the second length L2 may be longer than the first length L1 within the range of the length at which the intersection may be formed.

The first irradiation direction and the second irradiation direction may form a certain acute or obtuse angle with the rear surface P2 of the substrate SUB. That is, the first radiation direction and the second radiation direction may not be parallel to the rear surface P2. In some embodiments, the first irradiation direction and the second irradiation direction may not be perpendicular to the rear surface P2.

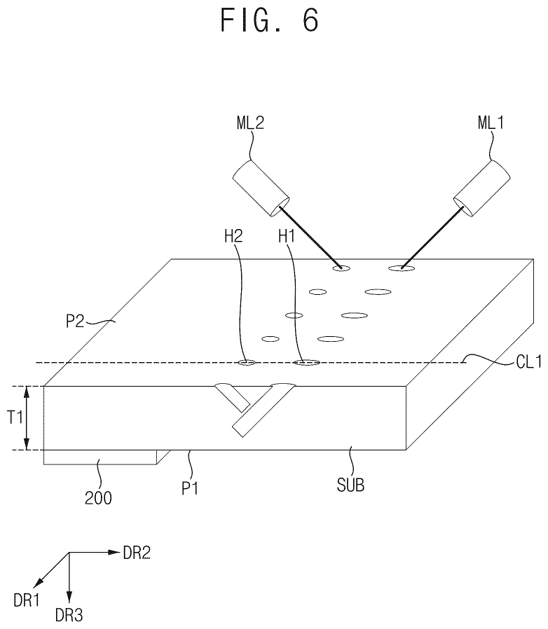

Referring to FIG. 6, in an embodiment, the method may include forming the first holes H1 such that a plurality of the first holes H1 may be arranged along the first direction DR1 on the rear surface P2 of the substrate SUB. Additionally, the method may include forming the second holes H2 such that a plurality of the second holes H2 may also be arranged along the first direction DR1 on the rear surface P2. Specifically, for example, the distance between the first holes H1 adjacent to each other in the first direction DR1 may be substantially equal to each other. In some embodiments, the distance between the second holes H2 adjacent to each other in the first direction DR1 may be substantially equal. However, aspects of the present disclosure are not limited thereto, and the distance between adjacent first holes H1 may be different. Additionally or alternatively, the distance between adjacent second holes H2 may also be different.

In an embodiment, the method may include forming the first hole H1 and the second hole H2 such that the first hole H1 and the second hole H2 are arranged side by side in the second direction DR2. Specifically, a first virtual center line CL1 passing through a center of the adjacent first hole H1 and a center of the second hole H2 may be parallel to the second direction DR2. That is, for example, the method may include forming a plurality of first holes H1 and a plurality of second holes H2 such that each of the plurality of first holes H1 and the plurality of second holes H2 are arranged side by side in the first direction DR1 on the rear surface P2. In some embodiments, a first hole H1 and a corresponding second hole H2 may be arranged in the second direction DR2 from the first hole H1. Accordingly, for example, the distance between adjacent holes H1 among the plurality of first holes H1 and the distance between adjacent holes H2 among the plurality of second holes H2 may be substantially equal. Accordingly, the plurality of first holes H1 and the plurality of second holes H2 may be arranged parallel to each other along the first direction DR1.

Although not shown in FIG. 6, in some embodiments, the direction in which the plurality of first holes H1 and the plurality of second holes H2 are arranged may not be limited to the first direction DR1. In some embodiments, the direction in which the first and second holes H1 and H2 adjacent to each other are arranged may not be limited to the second direction DR2. However, a direction in which each of the plurality of first holes H1 and the plurality of second holes H2 are arranged in a line and a direction a second hole H2 corresponding to a first hole H1 of the plurality of first holes H1 may be arranged may be vertical. For example, the plurality of first holes H1 and the plurality of second holes H2 may be arranged along the second direction DR2. In some embodiments, the direction in which a first hole H1 and a second hole H2 corresponding to the first hole H1 are arranged may be in the first direction DR1.

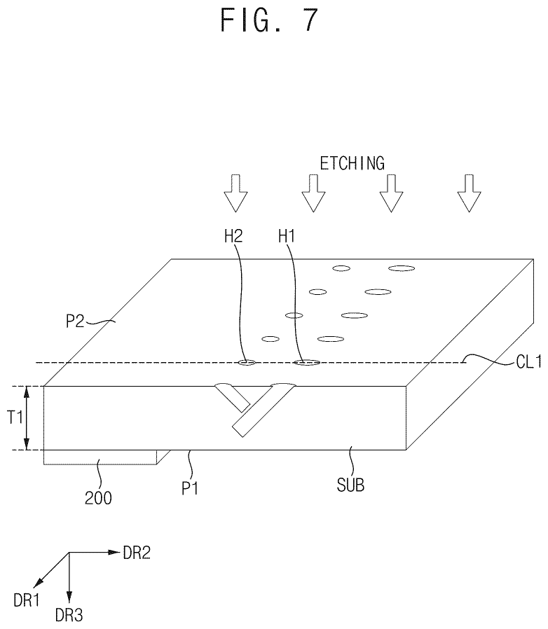

Referring to FIGS. 7 and 8, the method may include applying an etchant to the rear surface P2 of the substrate SUB. For example, the method may include filling the first hole H1 and the second hole H2 with the etchant. In other words, for example, the method may include filling in the plurality of first holes H1 and the plurality of second holes H2 using the etchant, and the method may include applying the etchant onto the rear surface P2 excluding the plurality of first holes H1 and the plurality of second holes H2. As shown in FIGS. 5, 6, and 7, the thickness of the substrate SUB in the third direction DR3 may be T1 before applying the etchant.

The first hole H1 and the second hole H2 adjacent to each other may meet through the etchant. The first hole H1 and the second hole H2 may extend to each other through the etchant and form the intersection point 166 at a point where the first hole H1 and the second hole H2 meet. A dummy substrate DSUB may be formed in the second direction DR2 based on the intersection point 166. The base substrate 100 may be formed in a direction opposite to the second direction DR2 based on the intersection point 166.

In an embodiment, the first hole H1 may be extended to the upper surface P1 through the etchant to form the dummy substrate DSUB including a third inclined surface S3. Specifically, as described herein, the etchant applied to the rear surface P2 of the substrate SUB may fill the first hole H1 and the second hole H2. Afterwards, for example, the first hole H1 and the second hole H2, which are adjacent to each other in the second direction DR2, may extend to meet each other. In some aspects, the plurality of first holes H1 and the plurality of second holes H2 adjacent to each other in the first direction DR1 extend along the first direction DR1, and the third inclined surface S3 may be formed in the second direction DR2 based on the intersection point 166. The first inclined surface 162 and the second inclined surface 164 may be formed in a direction opposite to the second direction DR2 based on the intersection point 166.

The method may include forming the first inclined surface 162 from the plurality of first holes H1. Specifically, for example, each of the plurality of first holes H1 may extend in the first irradiation direction through the etchant and meet the upper surface. In some aspects, each of the plurality of first holes H1 extending to the upper surface P1 may be connected to each other in the first direction DR1 through the etchant. Accordingly, the first inclined surface 162 may be formed. In some examples, the upper surface P1 may be the equal to the upper surface 120 of the base substrate 100.

The method may include forming the second inclined surface 164 from the plurality of second holes H2. Specifically, each of the plurality of second holes H2 may extend in the second irradiation direction through the etchant and meet adjacent first holes H1. Additionally, for example, each of the second holes H2 extending to the first holes H1 may be connected to each other in the first direction DR1 through the etchant. Accordingly, the second inclined surface 164 may be formed.

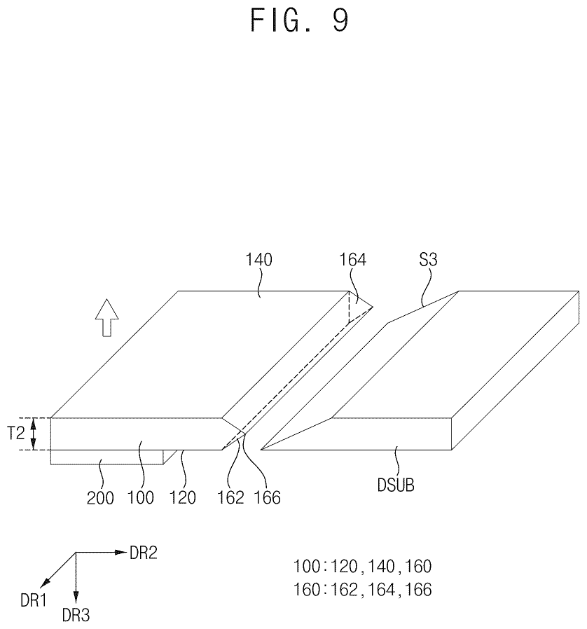

Referring to FIGS. 8 and 9, the method may include removing a portion of the substrate formed at an intersection of the second inclined surface 164, the third inclined surface S3, and the rear surface P2 through the etchant. Specifically, for example, the etchant may remove the triangular pillar-shaped three-dimensional shape surrounded by the second inclined surface 164, the third inclined surface S3, and the rear surface P2 from the substrate SUB. However, the three-dimensional shape may not be limited to a triangular pillar shape.

The method may include separating the base substrate 100 and the dummy substrate DSUB formed through an etching process from each other. For example, the method may include moving the base substrate 100 in a direction opposite to the third direction DR3. When separating the base substrate 100 from the dummy substrate DSUB, the method may include moving the base substrate 100 such that the base substrate 100 does not collide with the dummy substrate DSUB and a portion of the unetched substrate SUB. Accordingly, for example, the occurrence of cracks due to collision during the separation process of the base substrate 100 may be prevented.

In some embodiments, the techniques described herein for manufacturing a display device (e.g., the display device DD of FIG. 1) may refrain from using dummy substrate DSUB. In this case, the method may include using the base substrate 100 separated from the substrate SUB to manufacture the display device.

Through the manufacturing processes described with reference to FIGS. 5, 6, 7, 8, and 9, the base substrate 100 shown in FIG. 4 may be manufactured. The display panel 200, the polarizing member (POL), the adhesive member AM, and the window member WNL may be attached in the third direction DR3 onto the upper surface 120 of the manufactured base substrate 100, as shown in FIG. 1. The display device DD may be manufactured.

Although not shown in FIGS. 5, 6, 7, 8, and 9, the display panel 200 may not be attached to the upper surface P1 of the substrate SUB and the upper surface 120 of the base substrate 100. In an example, the method may include, after manufacturing the base substrate 100, attaching the display panel 200 to the upper surface 120 of the base substrate 100.

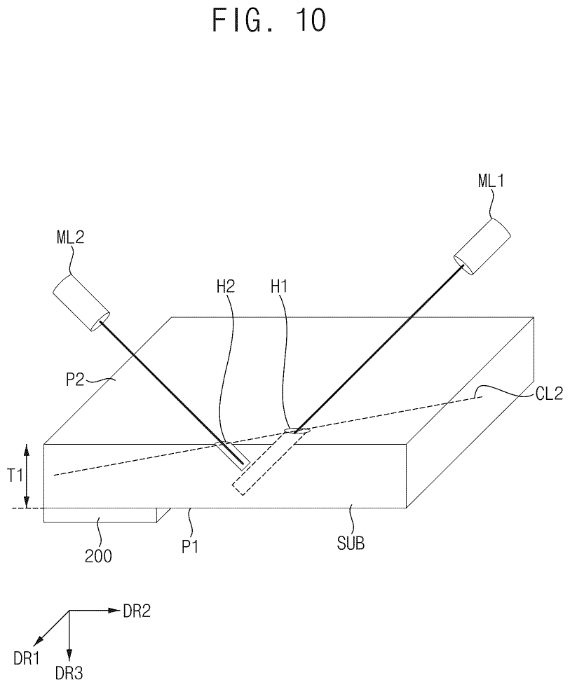

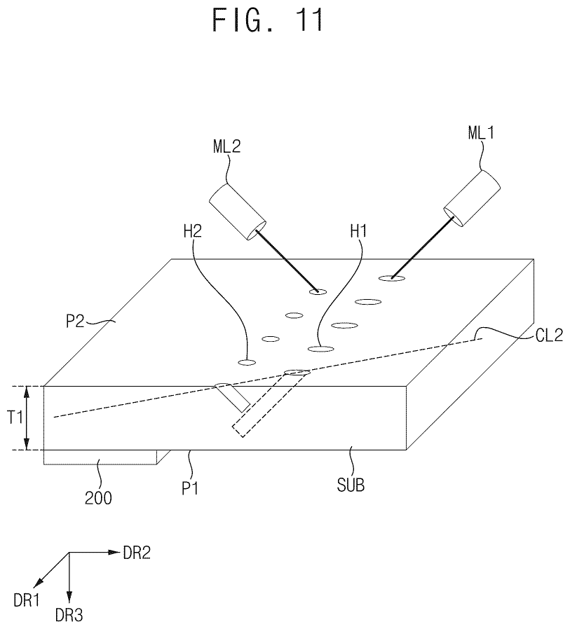

FIGS. 10 and 11 are perspective views illustrating a method of manufacturing a display device according to an embodiment.

The method of manufacturing the display device DD described with reference to FIGS. 10 and 11 may be substantially the same as the method of manufacturing the display device DD described with reference to FIGS. 5, 6, 7, 8, and 9 except for the first hole H1 and the second hole H2.

Hereinafter, repeated descriptions that overlap with the manufacturing method of the display device DD described with reference to FIGS. 5, 6, 7, 8, and 9 will be omitted or simplified.

Referring to FIG. 10, the method may include arranging the first hole H1 and the second hole H2 adjacent to each other, obliquely to the first direction DR1 and the second direction DR2. For example, a second virtual center line CL2 connecting the center of the first hole H1 and the center of the second hole H2 may be oriented a diagonal direction between the direction opposite to the first direction DR1 and the second direction DR2. Specifically, for example, a first straight line parallel to the second virtual center line CL2 and a second straight line parallel to the second direction DR2 may meet on the rear surface P2, and the angle formed by the first straight line and the second straight line may be an acute or obtuse angle. In other words, the first straight line and the second straight line may not be parallel to each other and may not meet perpendicularly.

Referring to FIG. 11, the first holes H1 adjacent to each other on the rear surface P2 may be arranged with the same distance in the first direction DR1. Expressed another way, the method may include forming the first holes H1 on the rear surface P2 such that the distance between adjacent first holes H1 in the first direction DR1 is the same. In some aspects, the second holes H1 adjacent to each other on the rear surface P2 may be arranged such that the distance between adjacent second holes H2 in the first direction DR1 is the same. The distance between adjacent first holes H1 among the plurality of first holes H1 and the distance between adjacent second holes H2 among the plurality of second holes H2 may substantially equal. Accordingly, for example, the method may include forming the plurality of first holes H1 and the plurality of second holes H2 according to a zig-zag arrangement on the rear surface P2 in the first direction DR1.

Through the manufacturing processes of FIGS. 10 and 11, the base substrate 100 shown in FIG. 4 may be manufactured. The positions at which the plurality of first holes H1 and the plurality of second holes H2 are arranged may be different from the manufacturing process of FIGS. 10 and 11 and the manufacturing process of FIGS. 5, 6, 7, 8, and 9. However, in some embodiments, the position where the edge area 160 is formed or the direction of protrusion may be substantially equal.

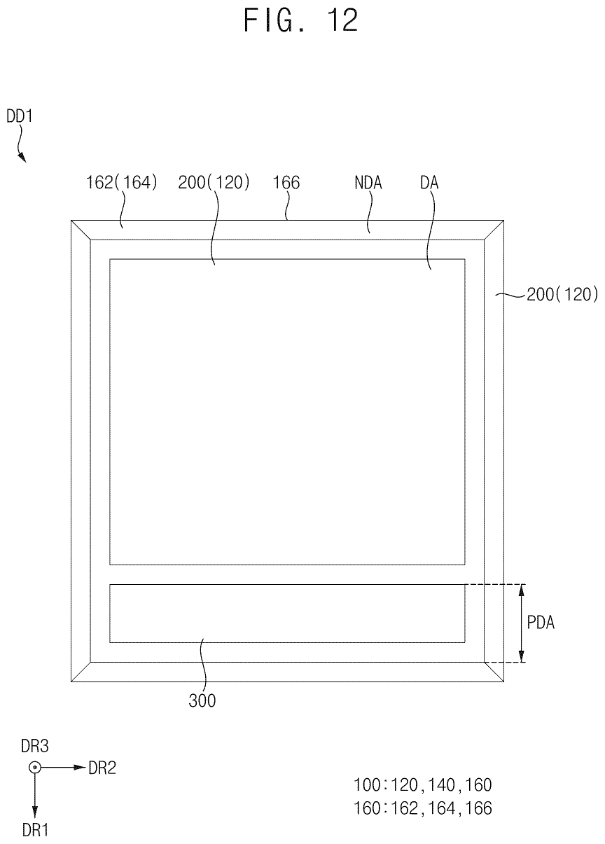

FIG. 12 is a plan view illustrating a display device DD1 according to an embodiment.

The display device DD1 described with reference to FIG. 12 may be substantially the same as the display device DD described with reference to FIGS. 1, 2, 3, and 4 except for a different location of the edge area 160. Hereinafter, repeated descriptions that overlap with the components of the display device DD described with reference to FIGS. 1, 2, 3, and 4 will be omitted or simplified.

Referring to FIG. 12, in an embodiment, the first inclined surface 162 may extend from at least one side of the four sides of the rectangle that overlaps the outer edge of the display area DA. Correspondingly, the rear surface 140 may also have four sides, and the second inclined surface 164 may extend from at least one of the four sides of the rear surface 140. Accordingly, for example, the first inclined surface 162 and the second inclined surface 164 may meet each other to form the intersection point 166, and at least one of the edge area 160 may be formed outside the display area DA.

In an embodiment, the first inclined surface 162 may extend from four sides of the upper surface 120. In some aspects, the second inclined surface 164 may extend from four sides of the rear surface 140. Specifically, for example, the first inclined surface 162 and the second inclined surface 164 corresponding to the first inclined surface 162 may be connected to all sides of the upper surface 120 and the rear surface 140, respectively. In other words, the first inclined surface 162 may be connected to all four sides of upper surface 120. In some aspects, the second inclined surface 164 may be connected to all four sides of the rear surface 140. In this case, the base substrate 100 may not include a side surface parallel to the third direction DR3. Accordingly, for example, the outermost areas of the display device DD, which are more relatively vulnerable than the internal areas of the display device DD, may be more easily protected and have increased protection.

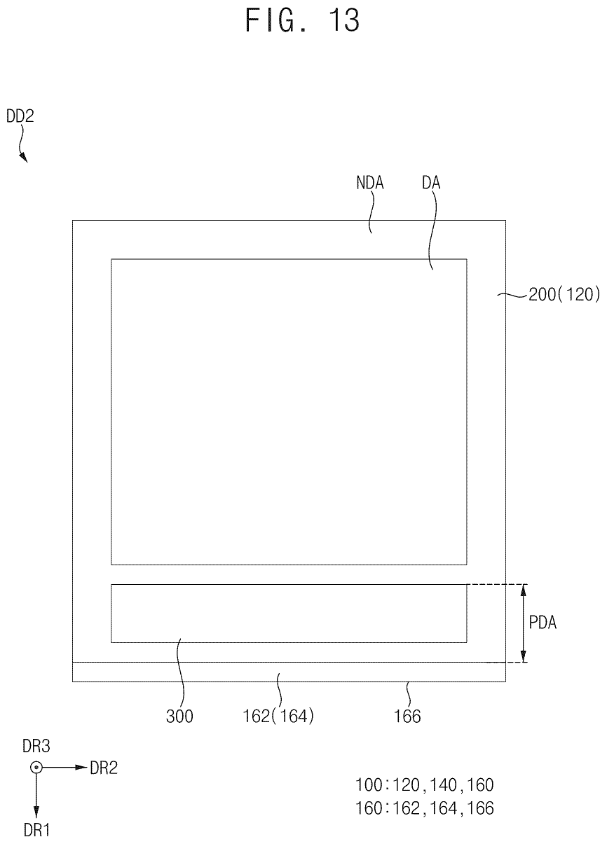

FIG. 13 is a plan view illustrating a display device DD2 according to an embodiment.

The display device DD2 described with reference to FIG. 13 may be substantially the same as the display device DD described with reference to FIGS. 1, 2, 3, and 4 except for a different location of the edge area 160. Hereinafter, repeated descriptions that overlap with the components of the display device DD described with reference to FIGS. 1, 2, 3, and 4 will be omitted or simplified.

Referring to FIG. 13, in an embodiment, the first inclined surface 162 may extend from one of the four sides adjacent to the pad area PDA. Specifically, for example, the edge area 160 may be disposed in an area that overlaps one side adjacent to the pad area PDA. Accordingly, for example, the impact resistance of the pad area PDA where the driving member 300 configured to transmit electrical signals to the plurality of pixels PX is disposed may be further improved.

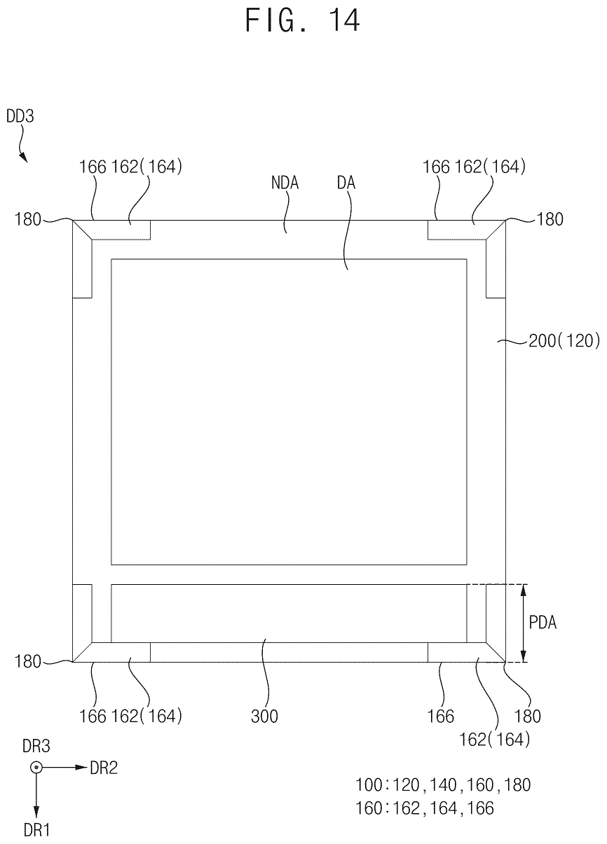

FIG. 14 is a plan view illustrating a display device according to an embodiment.

The display device DD3 described with reference to FIG. 14 may be substantially the same as the display device DD described with reference to FIGS. 1, 2, 3, and 4 except for a different location of the edge area 160. Hereinafter, repeated descriptions that overlap with the components of the display device DD described with reference to FIGS. 1, 2, 3, and 4 will be omitted or simplified.

Referring to FIG. 14, in an embodiment, the edge area 160 may be arranged to overlap at least one corner area 180 formed by meeting two adjacent sides among the four sides. In other words, for example, the first inclined surface 162 may extend from a portion of two sides which meet each other from among the four sides. In some aspects, the edge area 160 may be disposed in all corner areas 180 of the display device DD3.

In the present disclosure, the location of the edge area 160 is not limited to the examples described herein. For example, the edge area 160 may be formed in any area that may be combined with an area overlapping the corner area 180 and an area overlapping a plurality of sides.

A display device and a method of the display device according to the embodiments described herein may be applied to a display device included in a computer, a notebook, a mobile phone, a smartphone, a smart pad, a PMP, a PDA, an MP3 player, or the like.

Although the methods and the systems according to the embodiments have been described with reference to the drawings, the illustrated embodiments are examples, and may be modified and changed by a person having ordinary knowledge in the relevant technical field without departing from the technical spirit described in the following claims.

What is claimed is:

1. A display device comprising:
a base substrate divided into a display area and at least one edge area adjacent to the display area, the base substrate including an upper surface, a rear surface facing the upper surface, a first inclined surface forming a first inclined angle with the upper surface, and a second inclined surface forming a second inclined angle with the rear surface; and
a display panel disposed on the upper surface of the base substrate,
wherein the first inclined surface and the second inclined surface are defined in the at least one edge area.

2. The display device of claim 1, an intersection point, where the first inclined surface and the second inclined surface intersect, is defined on the base substrate.

3. The display device of claim 2, wherein the intersection point is located between a first plane extending in a direction parallel to the upper surface and a second plane extending in a direction parallel to the rear surface.

4. The display device of claim 3, wherein the intersection point is located on a virtual horizontal line that bisects a thickness of the base substrate.

5. The display device of claim 3, wherein a shortest distance from the first plane to the intersection point is substantially equal to a shortest distance from the second plane to the intersection point.

6. The display device of claim 1, wherein the first inclined angle is substantially equal to the second inclined angle.

7. The display device of claim 1, wherein the at least one edge area is adjacent to an outside of the display area.

8. The display device of claim 7, wherein:
the upper surface includes:
four sides that overlap the outside of the display area; and
at least one corner area formed by two adjacent sides included among the four sides and intersecting with each other, and
the first inclined surface extends from at least one of the four sides.

9. The display device of claim 8, wherein the base substrate further includes a pad area configured to transmit electrical signals to the display area, and
wherein the first inclined surface extends from a side included among the four sides and located adjacent to the pad area.

10. The display device of claim 8, wherein the at least one edge area overlaps the at least one corner area.

11. A method of manufacturing a display device, the method comprising:
forming at least one first hole in a first irradiation direction on a rear surface of a substrate, the substrate including an upper surface and the rear surface facing the upper surface;
forming at least one second hole in a second irradiation direction different from the first irradiation direction on the rear surface;
filling the at least one first hole and the at least one second hole with an etchant;
forming a first inclined surface along the at least one first hole;
forming a second inclined surface along the at least one second hole; and
forming a base substrate including the first inclined surface and the second inclined surface.

12. The method of claim 11, wherein the at least one first hole and the at least one second hole are spaced apart from each other.

13. The method of claim 11, wherein a length of the at least one first hole in the first irradiation direction is longer than a length of the at least one second hole in the second irradiation direction.

14. The method of claim 11, wherein forming the at least one first hole includes forming a plurality of first holes along a first direction parallel to the rear surface, and
wherein forming the at least one second hole includes forming a plurality of second holes along the first direction.

15. The method of claim 14, wherein the at least one first hole and the at least one second hole are arranged side by side in a second direction perpendicular to the first direction.

16. The method of claim 14, wherein the at least one first hole and the at least one second hole are arranged obliquely to the first direction and a second direction perpendicular to the first direction.

17. The method of claim 11, wherein forming the first inclined surface includes forming a dummy substrate including a third inclined surface by extending the at least one first hole to the upper surface through the etchant; and
wherein forming of the base substrate includes separating the base substrate from the dummy substrate.

18. The method of claim 17, wherein forming the dummy substrate includes removing a portion of the substrate using the etchant, and
wherein the portion is formed at an intersection of the second inclined surface, the third inclined surface, and the rear surface.

19. The method of claim 11, wherein filling the etchant includes applying the etchant on the rear surface of the substrate.

20. The method of claim 11, wherein an intersection point, where the first inclined surface and the second inclined surface intersect, is located between a first plane extending in a direction parallel to the upper surface and a second plane extending in a direction parallel to the rear surface.
